(19) United States
(12) Patent Application Publication
(10) Pub. No.: US 2024/0224704 A1
(43) Pub. Date: Jul. 4, 2024

(54) DISPLAY DEVICE

(71) Applicant: LG DISPLAY CO., LTD., Seoul (KR)

(72) Inventors: Eun Hee CHOI, Paju-si (KR); Ji Gon KIM, Paju-si (KR); Dae Yong KIM, Paju-si (KR)

(73) Assignee: LG DISPLAY CO., LTD., Seoul (KR)

(21) Appl. No.: 18/538,250

(22) Filed: Dec. 13, 2023

(30) Foreign Application Priority Data
Dec. 29, 2022 (KR) 10-2022-0189353

(51) Int. Cl. H10K 59/65; H10K 59/121; H10K 59/126; H10K 59/80

(52) U.S. Cl. CPC H10K 59/65; H10K 59/121; H10K 59/126; H10K 59/80518; H10K 2102/103

(57) ABSTRACT

Embodiments disclose a display device including a display panel including a first display region in which a plurality of first pixels are disposed, a second display region including pixel regions in which a plurality of second pixels are disposed and a plurality of light-transmitting regions, and an opening/closing module configured to control light passing through the plurality of light-transmitting regions, and an optical sensor disposed below the display panel, wherein the opening/closing module opens the light-transmitting region when the optical sensor is driven, and blocks the light-transmitting region when the optical sensor is not driven.

### CROSS-REFERENCE TO RELATED APPLICATION

This application claims priority to and the benefit of Korean Patent Application No. 10-2022-0189353, filed on Dec. 29, 2022, the disclosure of which is incorporated herein by reference in its entirety.

### BACKGROUND

### 1. Technical Field

The present disclosure relates to a display device.

### 2. Discussion of the Related Art

Electroluminescence display devices may be classified into inorganic light-emitting display devices and organic light-emitting display devices, depending on materials of an emission layer. An active-matrix-type organic light-emitting display device includes an organic light-emitting diode (OLED) that emits light by itself and has advantages in terms of a quick response time, high luminous efficiency, high luminance, and a wide viewing angle. The organic light-emitting display device may have an OLED formed in each pixel. The organic light-emitting display device may be able to represent a perfect black, as well as having a quick response time, high luminous efficiency, high luminance, a wide viewing angle, and an excellent contrast ratio and color gamut.

Recently, multimedia functions of a mobile terminal have been improved. For example, a camera is basically built in a mobile terminal and the resolution of the camera is increasing to a level of an existing digital camera. However, a front camera of the mobile terminal limits the design of a screen, thereby making it difficult to design the screen. In order to reduce a space occupied by the camera, a screen design including a notch or a punch hole has been adopted in the mobile terminal, but it is difficult to implement a full-screen display because a screen size is still limited due to the camera.

In order to implement a full-screen display, a method of preparing a display panel having an imaging region in which low-resolution pixels are disposed in a screen of the display panel, and of disposing a camera and/or various sensors in or under the imaging region, has been proposed.

### SUMMARY

Accordingly, embodiments of the present disclosure are directed to a display device that substantially obviates one or more of the problems due to limitations and disadvantages of the related art.

An aspect of the present disclosure is to provide a display device having a display region in which an imaging region is provided, and in which the imaging region is not visible from the outside.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a display panel including a first display region in which a plurality of first pixels are disposed, a second display region including pixel regions in which a plurality of second pixels are disposed and a plurality of light-transmitting regions, and an opening/closing module configured to control light passing through the plurality of light-transmitting regions, and an optical sensor disposed below the display panel, wherein the opening/closing module is configured to open the light-transmitting region when the optical sensor is driven, and to block the light-transmitting region when the optical sensor is not driven. The second display region may be an imaging region, e.g. an imaging region under which the optical sensor is located. An invention is defined in the appended claims.

A pixel density of the second display region may be lower than a pixel density of the first display region.

The display panel may include a plurality of third pixels disposed in the plurality of light-transmitting regions.

A pixel density of the second display region may be equal to a pixel density of the first display region.

The opening/closing module may be configured to open the light-transmitting region when an image is output from the third pixels.

The opening/closing module may be configured to block the light-transmitting region when the optical sensor and the third pixels are not driven.

A first anode driving the second pixel may be a reflective electrode, and a second anode driving the third pixel may be a transparent electrode.

The light-transmitting region may include a buffer layer disposed on a substrate, a gate insulating film disposed on the buffer layer, and a cathode disposed on the gate insulating film, and the opening/closing module may be disposed on the cathode.

The opening/closing module may include a first transparent electrode, a light-blocking layer disposed on the first transparent electrode, and a second transparent electrode disposed on the light-blocking layer, wherein the light-blocking layer may include a first light-blocking portion disposed at a position corresponding to each of the plurality of light-transmitting regions.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a conceptual diagram of a display device according to an example of the present disclosure;

FIG. 2 is a cross-sectional view schematically illustrating a display panel according to the example of the present disclosure;

FIG. 3 is a view illustrating a pixel arrangement in a display region according to the example of the present disclosure;

FIG. 4 is a view illustrating pixels and light-transmitting regions of a second display region;

FIG. 5 is a view schematically illustrating a display device according to a first example of the present disclosure;

FIG. 6 is a view illustrating a state in which a light-blocking layer is disposed in a second display region;

FIG. 7A is a view illustrating an opening/closing module according to one example of the present disclosure;

FIGS. 7B and 7C illustrate modified examples of FIG. 7A;

FIG. 8A is a view illustrating an electrode pattern for applying power to a plurality of light-blocking portions;

FIG. 8B illustrates a modified example of FIG. 8A;

FIGS. 9 to 11 are views illustrating various light-blocking structures;

FIG. 12 is a view illustrating a state in which light is blocked by the light-blocking portion and a camera is not visible;

FIG. 13 is a view illustrating a state in which the light-blocking portion is open and light is incident on the camera;

FIG. 14 is an exemplary view illustrating a schematic cross-sectional structure of the second display region according to the first example of the present disclosure;

FIG. 15 is an exemplary view illustrating a detailed cross-sectional structure of the second display region according to the first example of the present disclosure;

FIG. 16 is a view schematically illustrating a display device according to a second example of the present disclosure;

FIG. 17 is a view illustrating a state in which a third pixel is disposed in a light-transmitting region;

FIG. 18 is a view illustrating a state in which an image is output from the third pixel disposed in the light-transmitting region;

FIG. 19 is a view illustrating a state in which light is incident on a camera;

FIG. 20 is an exemplary view illustrating a schematic cross-sectional structure of a second display region according to the second example of the present disclosure;

FIG. 21 is an exemplary view illustrating a detailed cross-sectional structure of the second display region according to the second example of the present disclosure;

FIG. 22 is a view schematically illustrating a display device according to a third example of the present disclosure;

FIG. 23 is a view illustrating a state in which a light-blocking portion is open and an image is output from a third pixel disposed in a light-transmitting region;

FIG. 24 is a view illustrating a state in which a light-blocking portion is open and light is incident on a camera;

FIG. 25 is a view illustrating a state in which the light-blocking portion blocks light;

FIG. 26 is an exemplary view illustrating a schematic cross-sectional structure of a second display region according to the third example;

FIG. 27 is an exemplary view illustrating a detailed cross-sectional structure of the second display region according to the third example;

FIG. 28 is a view schematically illustrating a display device according to a fourth example of the present disclosure;

FIG. 29 is a view illustrating a state in which an image is output from a third pixel disposed in a light-transmitting region;

FIG. 30 is a view illustrating a state in which light is incident on a camera; and

FIG. 31 is a flowchart illustrating a method of driving a display device according to one example of the present disclosure.

### DETAILED DESCRIPTION

Advantages and features of the present disclosure and implementation methods thereof will be clarified through the following examples described with reference to the accompanying drawings. However, the present disclosure is not limited to the examples described below and may be implemented with a variety of different forms. The examples are merely provided to allow those skilled in the art to completely understand the scope of the present disclosure, and the present disclosure is defined only by the scope of the claims.

The figures, dimensions, ratios, angles, numbers, and the like disclosed in the drawings for describing the examples of the present disclosure are merely illustrative and are not limited to details shown in the present disclosure. Throughout the specification, like reference numerals refer to like elements. Further, in describing the present disclosure, detailed descriptions of well-known technologies will be omitted when it is determined that they may unnecessarily obscure the gist of the present disclosure.

Terms such as “including,” “having”, “composed of” and “comprising” used herein are intended to allow other elements to be added unless the terms are used with the term “only.” Any references to the singular may include the plural unless expressly stated otherwise.

Components are interpreted as including an ordinary error range even if not expressly stated.

For description of a positional relationship, for example, when the positional relationship between two parts is described as “on,” “above,” “below,” and “next to,” or the like, one or more parts may be interposed therebetween unless the term “immediately” or “directly” is used in the expression.

In the description of embodiments, the terms “first,” “second,” and the like may be used herein to describe various components, the components are not limited by the terms. These terms are used only to distinguish one component from another. Accordingly, a first component described below could be termed a second component without departing from the technical spirit of the present disclosure.

Throughout the specification, like reference numerals refer to like elements.

The features of various examples may be partially or entirely combined with each other. The examples may be interoperated and performed in technically various ways and may be carried out independently of or in association with each other.

Hereinafter, various examples of the present disclosure will be described in detail with reference to the accompanying drawings.

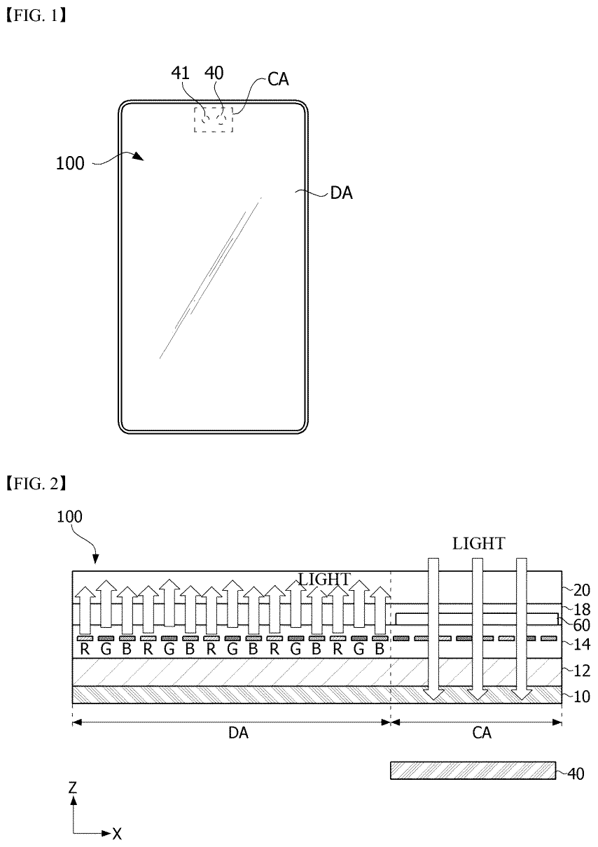

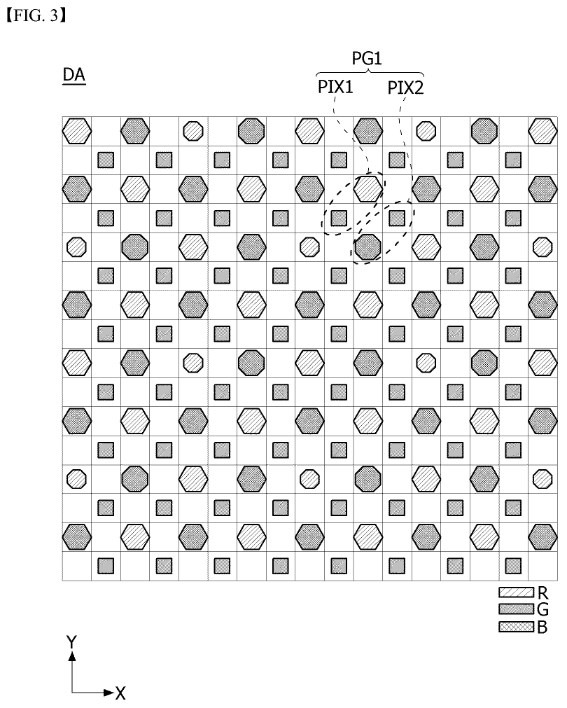

FIG. 1 is a conceptual diagram of a display device according to one example of the present disclosure. FIG. 2 is a cross-sectional view schematically illustrating a display panel according to the example of the present disclosure. FIG. 3 is a view illustrating a pixel arrangement in a display region according to one example of the present disclosure.

Referring to FIG. 1, in the display device according to the example, a front surface of a display panel 100 may be configured as a display region. Accordingly, a full-screen display can be enabled.

The display region may include a first display region DA and a second display region CA. The first display region DA and the second display region CA may both output images, but may have different resolutions from each other. As an example, the resolution of a plurality of second pixels disposed in the second display region CA may be lower than the resolution of a plurality of first pixels disposed in the first display region DA. A sufficient amount of light may be injected into electronic devices 40 and 41 disposed in the second display region CA by as much as the resolution lowered in the plurality of second pixels disposed in the second display region CA. In particular, since a number of the plurality of second pixels including pixel circuit decreases in the second display region CA, an area through which light can pass may increase in the second display area CA.

However, the present disclosure is not necessarily limited thereto, and the resolution of the first display region DA and the resolution of the second display region CA may be substantially the same.

The second display region CA may be a region in which one or more electronic devices 40 and 41 are disposed. The second display region CA is a region that may overlap various electronic devices. It may be smaller in area than that of the first display region DA outputting most of the image.

The electronic devices 40 and 41 may include at least one of an image sensor, an infrared sensor, a proximity sensor, an illumination sensor, a gesture sensor, a motion sensor, a fingerprint recognition sensor, and a biometric sensor. As an example, a first electronic device 41 may be an illumination sensor, and a second electronic device 40 may be a camera configured to capture an image or a video, but the present disclosure is not necessarily limited thereto, and various image-capturing units (optical sensors) may be selected.

Referring to FIGS. 2 and 3, the first display region DA and the second display region CA may include a pixel array in which pixels, to which pixel data is written, are disposed. The number of pixels per unit area (pixels per inch (PPI)) of the second display region CA may be lower than that of the first display region DA in order to ensure light transmittance of the second display region CA. However, the present disclosure is not necessarily limited thereto, and the PPI of each of the first display region DA and the second display region CA may be formed in the same or similar manner.

In the second display region CA, external light may pass through the display panel 100 through light-transmitting regions having high light transmittance and may be received by a camera placed below, e.g. under, the display panel 100.

Since both the first display region DA and the second display region CA include the pixels, an input image may be reproduced in the first display region DA and the second display region CA.

Each of the pixels of the first display region DA and the second display region CA may include sub-pixels having different colors to implement a color of an image. The sub-pixels may include red (red sub-pixel), green (green sub-pixel), and blue (blue sub-pixel). Although not shown in the drawings, each of the pixels may further include a white sub-pixel. Each of the sub-pixels disposed in the pixel region may include a pixel circuit and a light-emitting element (organic light-emitting diode (OLED)).

When in an image capturing mode, the camera 40 may capture an external image and output photo or video image data. In the image capturing mode, external light may be incident on the camera 40 through the second display region CA, and the camera 40 may capture an external image and output photo or video image data.

An opening/closing module 60 may be disposed in the second display region CA and may control light that is incident on the display device 100 at the second display region CA. The opening/closing module 60 may pass light through the second display region CA when the camera 40 is driven, and block light incident on the second display region CA when the camera 40 is not driven. The opening/closing module 60 may be an optical shutter that passes or blocks light.

The display panel 100 has a width in an X-axis direction, a length in a Y-axis direction, and a thickness in a Z-axis direction. The display panel 100 may include a circuit layer 12 disposed on a substrate 10, and a light-emitting element layer 14 disposed on the circuit layer 12. A polarizing plate 18 may be disposed on the light-emitting element layer 14, and a cover glass 20 may be disposed on the polarizing plate 18.

The circuit layer 12 may include a pixel circuit connected to lines such as data lines, gate lines, power lines, and the like, a gate driving unit connected to the gate lines, and the like.

The circuit layer 12 may include circuit elements such as a driving transistor implemented as a thin-film transistor (TFT), a capacitor, and the like. The lines and circuit elements of the circuit layer 12 may be implemented with a plurality of insulating layers, two or more metal layers separated from each other with the insulating layers therebetween, and an active layer including a semiconductor material.

The light-emitting element layer 14 may include a light-emitting element driven by the pixel circuit. The light-emitting element may be implemented as an OLED. The OLED may include an organic compound layer formed between an anode and a cathode.

The organic compound layer may include a hole injection layer HTL, a hole transport layer HTL, an emission layer EML, an electron transport layer ETL, and an electron injection layer EIL, but the present disclosure is not limited thereto.

When a voltage is applied to the anode and the cathode of the OLED, holes passing through the hole transport layer HTL and electrons passing through the electron transport layer ETL move to the emission layer EML to create excitons, and thus visible light is emitted from the emission layer EML.

The light-emitting element layer 14 may further include a color filter array disposed on the pixels that selectively transmit light of red, green, and blue wavelengths.

The light-emitting element layer 14 may be covered by a protective film, and the protective film may be covered by an encapsulation layer.

The protective film and the encapsulation layer may have a structure in which organic films and inorganic films are alternately stacked. The inorganic films may block the penetration of moisture or oxygen. The organic films may planarize a surface of the inorganic film.

When the organic films and the inorganic films are stacked in multiple layers, the penetration of moisture/oxygen affecting the light-emitting element layer 14 may be effectively blocked since a movement path of the moisture or oxygen is increased in length as compared with a single layer.

The polarizing plate 18 may be adhered to the encapsulation layer. The polarizing plate 18 can improve outdoor visibility of the display device. The polarizing plate 18 may reduce the reflection of light from a surface of the display panel 100 and block the light reflected from metal of the circuit layer 12, thereby improving brightness of the pixels. The polarizing plate 18 may be implemented as a polarizing plate to which a linear polarizing plate and a phase retardation film are bonded, or a circular polarizing plate.

Referring to FIG. 3, the first display region DA may include first pixels PG1 arranged in a matrix form. Each of the first pixels PG1 may be implemented as a real-type pixel in which R, G, and B sub-pixels of three primary colors form one pixel.

The first pixel PG1 may further include a white (W) sub-pixel, which is omitted from the drawing. In addition, two sub-pixels may form one pixel using a sub-pixel rendering algorithm. For example, a first pixel group PIX1 may include R and G sub-pixels, and a second pixel group PIX2 may include B and G sub-pixels. Insufficient color representation in the first pixel PG1 may be compensated with an average value of pieces of corresponding color data between neighboring pixels.

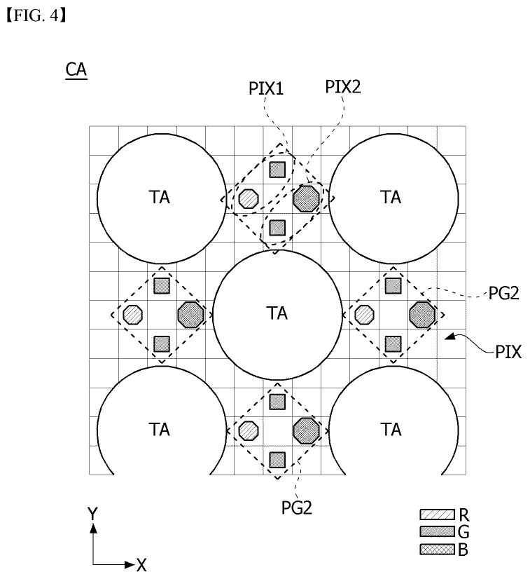

Referring to FIG. 4, the second display region CA may include a plurality of pixel regions PIX and a plurality of light-transmitting regions TA disposed between the plurality of pixel regions PIX (e.g. disposed so as not to overlap with the plurality of pixel regions PIX). The plurality of pixel regions PIX may be arranged as a first array in the second display region CA, and the plurality of light-transmitting regions TA may be arranged as a second array in the second light display region CA. The first and second arrays may be offset from one another so that the pixel regions PIX do not overlap with the light-transmitting regions TA. Each of the light-transmitting regions TA may include transparent media having high light transmittance. Each light transmitting region TA may also be free of metal. Accordingly, light may be incident with minimum light loss or reflection. Each light-transmitting region TA may be defined as a region made of transparent insulating materials without including metal lines or pixels. As the light-transmitting region TA becomes larger, the light transmittance of the second display region CA may be higher.

The shape of the light-transmitting region TA is illustrated in a circular shape, but the present disclosure is not limited thereto. For example, the light-transmitting region TA may be designed in various shapes such as a circular shape, an elliptical shape, a polygonal shape, or the like.

According to the example, since the plurality of light-transmitting regions are disposed in the second display region, the amount of light incident on the camera increases, thereby improving lens performance, in particular improving modulation transfer function (MTF) performance. The MTF performance is an index indicating the performance of a camera or lens. When the amount of incident light is insufficient, the MTF performance is degraded, resulting in data distortion.

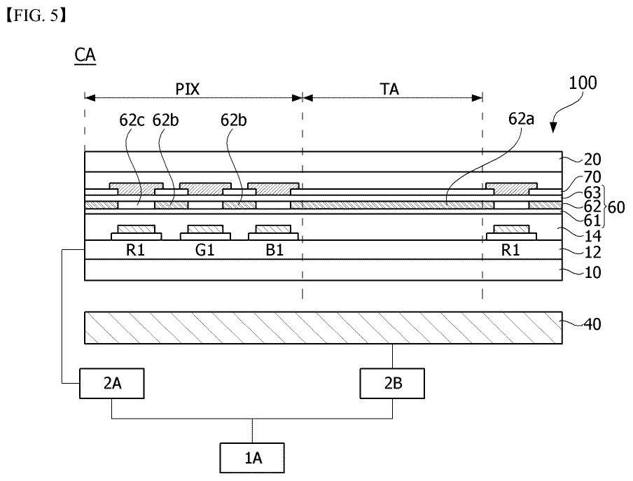

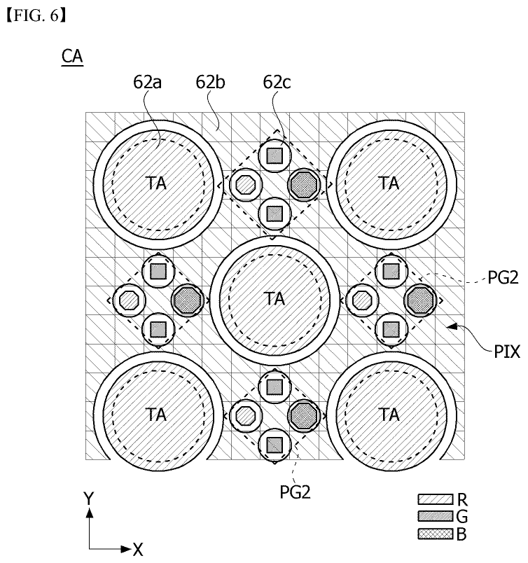

FIG. 5 is a view schematically illustrating a display device according to a first example of the present disclosure. FIG. 6 is a view illustrating a state in which a light-blocking layer is disposed in a second display region.

Referring to FIG. 5, the display device according to the example may include a display panel control unit 2A configured to receive a display panel control signal from a main processor 1A and a camera control unit 2B configured to receive a camera control signal.

The camera control unit 2B may control an operation of a camera 40 according to a timing signal received from the main processor 1A, and the display panel control unit 2A may control a display panel 100 and an opening/closing module 60 according to a control signal received from the main processor 1A.

The main processor 1A may be a main circuit board of a television system, a set-top box, a navigation system, a personal computer (PC), a vehicle system, a home theater system, a mobile device, or a wearable device.

The display panel control unit 2A may include a timing controller. The timing controller may receive pixel data of an input image, an opening/closing module control signal, and a timing signal from the main processor 1A, and output a control signal to a gate driving unit, a data driving unit, and an opening/closing module driving unit.

The opening/closing module driving unit (not shown) may output an opening/closing module on/off signal synchronized with a camera driving timing to the opening/closing module 60. The display panel control unit, the gate driving unit, the data driving unit, and the opening/closing module driving unit may be implemented in one driver integrated circuit (IC).

The display device according to the example controls the opening/closing module 60 to allow light to pass through a light-transmitting region TA when the camera 40 is driven, so that sufficient light may be incident on the camera 40. In addition, the display device may control the opening/closing module 60 to block the light-transmitting region TA when the camera 40 is not driven, so that the camera 40 is not visible from the outside. Accordingly, MTF performance of the camera 40 is improved by injecting a sufficient amount of light into the camera 40, disadvantages in which patterns of a second display region CA are visible from the outside by external light or the camera 40 is recognized from the outside by external light, may be overcome by blocking the light-transmitting region TA when the camera 40 is not driven.

However, the present disclosure is not necessarily limited thereto, and in addition to the camera 40, various optical sensors may be applied. That is, when the optical sensor is not driven, the light-transmitting region may be blocked, and when the optical sensor is driven, the light-transmitting region may be open.

The opening/closing module 60 may include a first transparent electrode 61, a light-blocking layer 62, and a second transparent electrode 63. The light-blocking layer 62 may be sandwiched between the first transparent electrode 61 and the second transparent electrode 63. An electrode material having high light transmittance such as indium-tin-oxide (ITO) may be selected for each of the first transparent electrode 61 and the second transparent electrode 63. The light-blocking layer 62 may include various light blocking materials capable of blocking (or absorbing) light during normal operation and transmitting light when a voltage is applied.

Referring to FIGS. 5 and 6, the light-blocking layer 62 may include a plurality of first light-blocking portions 62a disposed in the plurality of light-transmitting regions TA and a second light-blocking portion 62b surrounding the plurality of first light-blocking portions 62a. The second light-blocking portion 62b is disposed in a pixel region PIX, and may include openings 62c exposing sub-pixels R1, G1, and B1.

The first light-blocking portion 62a is disposed in the light-transmitting region TA, and may serve to selectively block or transmit light as power is applied.

Power is not supplied to the second light-blocking portion 62b, and thus the second light-blocking portion 62b may serve as a black matrix that always blocks light. That is, the second light-blocking portion 62b may partition each of the sub-pixels R1, G1, and B1 disposed in the second display region CA to prevent mixing of colors incident on a color filter 70 disposed on the opening/closing module 60. Accordingly, a contrast ratio of the emitted light may be improved.

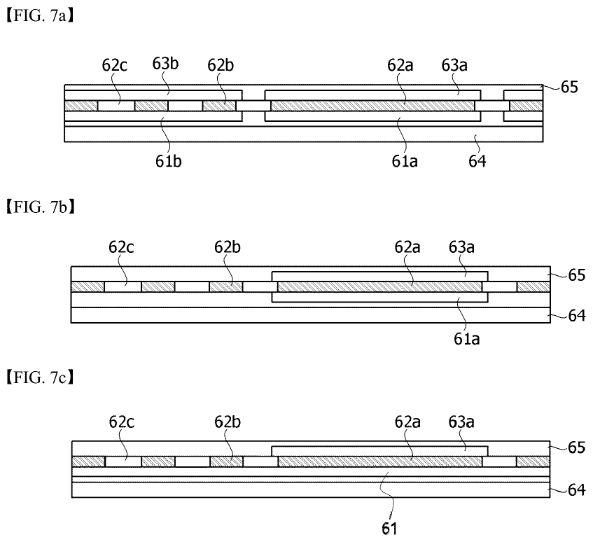

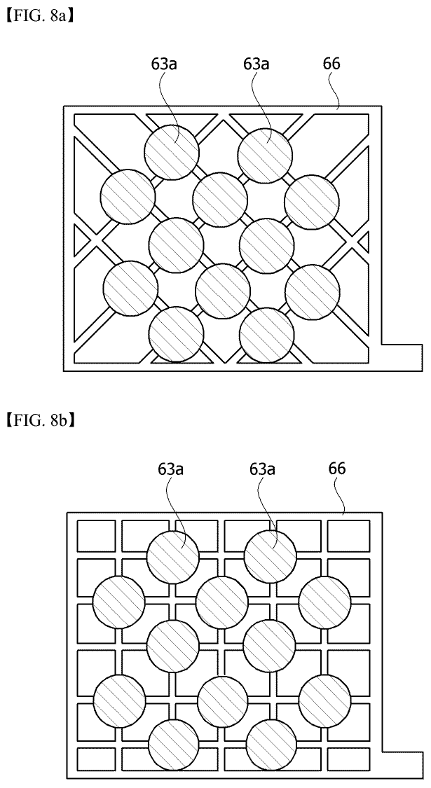

FIG. 7A is a view illustrating the opening/closing module according to one example of the present disclosure. FIGS. 7B and 7C illustrate modified examples of FIG. 7A. FIG. 8A is a view illustrating an electrode pattern for applying power to the plurality of light-blocking portions. FIG. 8B illustrates a modified example of FIG. 8A.

Referring to FIG. 7A, the first transparent electrode 61 and the second transparent electrode 63 of the opening/closing module 60 may be entirely formed in both the pixel region PIX and in the light-transmitting region TA of the second display region CA. However, a first transparent electrode 61a disposed below the first light-blocking portion 62a of the light-transmitting region TA and a first transparent electrode 61b disposed below the second light-blocking portion 62b of the pixel region PIX may be electrically isolated from each other. In addition, a second transparent electrode 63a disposed on the first light-blocking portion 62a and a second transparent electrode 63b disposed on the second light-blocking portion 62b may be electrically isolated from each other. Accordingly, power may be independently applied to the first light-blocking portion 62a of the light-transmitting region TA and/or to the second light-blocking portion 62b of the pixel region PIX. For example, power may be supplied to the second light-blocking portion 62b to control opening/closing of the light-transmitting region TA, without altering the pixel region PIX.

Referring to FIG. 7B, the first transparent electrode 61a and the second transparent electrode 63a may be disposed only on and below the first light-blocking portion 62a of the light-transmitting region TA. Referring to FIG. 7C, the first transparent electrode 61 may be entirely formed below the second display region CA, while the second transparent electrode 63a may only be disposed over the first light-blocking portion.

Referring to FIGS. 8A and 8B, the first transparent electrode 61 or the second transparent electrode 63 may include a plurality of transparent patterns 63a disposed on the plurality of first light-blocking portions 62a and a line electrode 66 connecting the plurality of transparent patterns 63a. Accordingly, power may be selectively applied only to the first light-blocking portion 62a. The transparent pattern 63a may be formed by patterning the first transparent electrode 61 or the second transparent electrode 63.

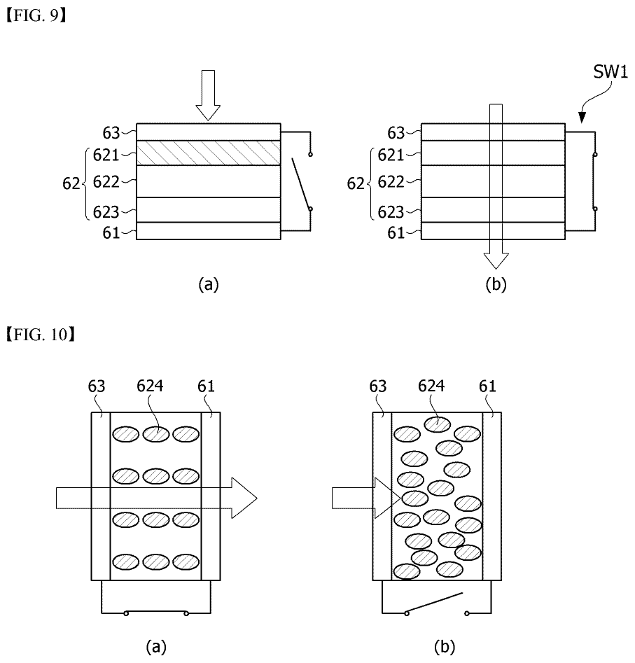

FIGS. 9 to 11 are views illustrating various light-blocking structures.

Referring to FIG. 9, the light-blocking layer 62 may include an ion storage layer 623, an electrolyte layer 622, and a photochromic material layer 621 whose light transmittance is changed by an oxidation-reduction reaction (an electrochromic structure). A photochromic material may selectively transmit light by an oxidation-reduction reaction when power is applied.

When a switch SW1 is closed (turned on) such that power is applied by the first transparent electrode 61 and the second transparent electrode 63, ions of the ion storage layer 623 may pass through the electrolyte layer 622 and flow into the photochromic material layer 621. The photochromic material layer 621 may transmit light by an oxidation-reduction reaction according to the inflow of ions. Therefore, when the switch (SW1) is closed (turned on), the photochromic material layer 621 transmits light; and when the switch (SW1) is open (turned off), the photochromic material layer 621 blocks light.

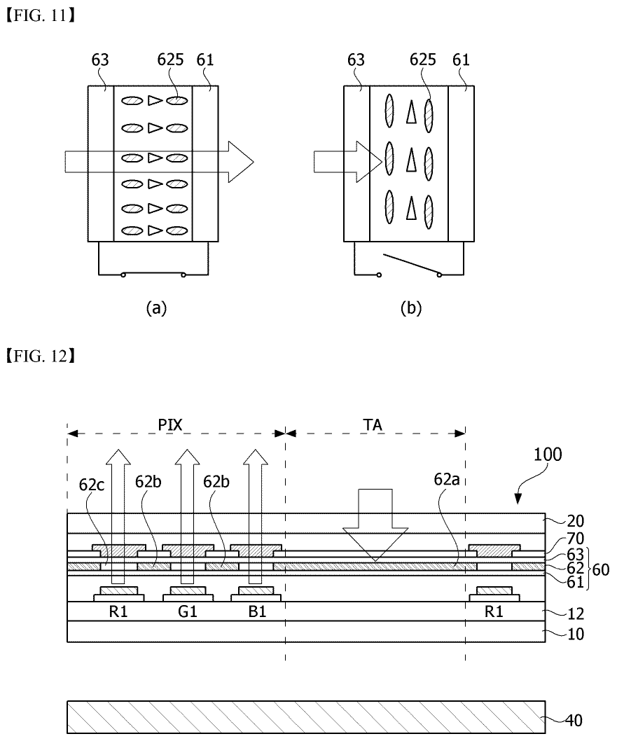

In addition, referring to FIG. 10, the opening/closing module 60 may change transmittance thereof according to a method of polarizing polarization particles in polymer particles 624. Alternatively, as shown in FIG. 11, the transmittance may be changed according to the polarization of a liquid crystal 625 and a dye having liquid crystal properties. The liquid crystal may be a cholesteric liquid crystal, but the present disclosure is not necessarily limited thereto.

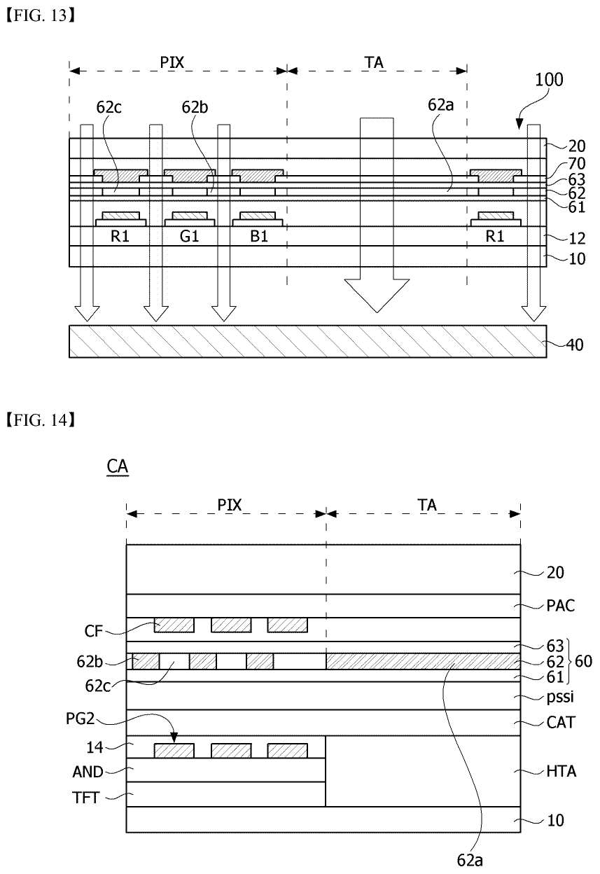

FIG. 12 is a view illustrating a state in which light is blocked by the light-blocking portion and the camera is not visible. FIG. 13 is a view illustrating a state in which the light-blocking portion is open and light is incident on the camera.

Referring to FIG. 12, when the camera 40 is not driven, the opening/closing module 60 may operate in a light-blocking mode in which light incident on the light-transmitting region TA is blocked by not applying power to the first transparent electrode 61 and/or the second transparent electrode 63. Accordingly, even when external light is incident, the pattern of the light-transmitting region TA and the camera 40 disposed below the panel may not be visible.

In such a light-blocking mode, the second light-blocking portion 62b partitions each of the sub-pixels in the pixel region PIX to prevent colors incident on the color filter 70 disposed on the opening/closing module 60 from being mixed. Accordingly, the contrast ratio of the emitted light may be improved.

Referring to FIG. 13, when the camera 40 is driven, the opening/closing module 60 applies power to the first transparent electrode 61 and the second transparent electrode 63 to switch the first light-blocking portion 62a to a light transmitting mode, thereby allowing light to be incident on the light-transmitting region TA. Accordingly, sufficient light may be incident on the camera 40 in the light-transmitting region TA. As a result, MTF performance of the camera 40 is improved, thereby reducing noise.

At this time, the second light-blocking portion 62b disposed between the pixels may continue to block light. However, the present disclosure is not necessarily limited thereto, and when the first light-blocking portion 62a operates in the light transmitting mode for transmitting light, the second light-blocking portion 62b may also be switched to transmit the light. This configuration may further improve the performance of the camera 40 by increasing the overall amount of light transmitted to the second display region CA.

Referring to FIG. 14, the second display region CA may be divided into the light-transmitting region TA and the pixel region PIX on a substrate 10. The pixel region PIX may include an anode AND and a light-emitting element layer 14 that are disposed on a driving circuit thin-film transistor (TFT). On the other hand, the light-transmitting region TA may include a high light-transmitting region HTA formed on the substrate 10. The high light-transmitting region HTA may be defined as a region which has a relatively high transmittance and in which only a plurality of organic/inorganic layers are present and a metal material that shields light is removed as much as possible between a cathode CAT and the substrate 10.

The cathode CAT and the opening/closing module 60 may be disposed in the pixel region PIX and the light-transmitting region TA. A passivation layer pssi may be disposed between the cathode CAT and the opening/closing module 60. The first light-blocking portion 62a of the opening/closing module 60 may be disposed in the light-transmitting region TA, and the second light-blocking portion 62b may be disposed in the pixel region PIX. A color filter CF, a planarization film PAC, and a cover glass 20 may be disposed on the opening/closing module 60.

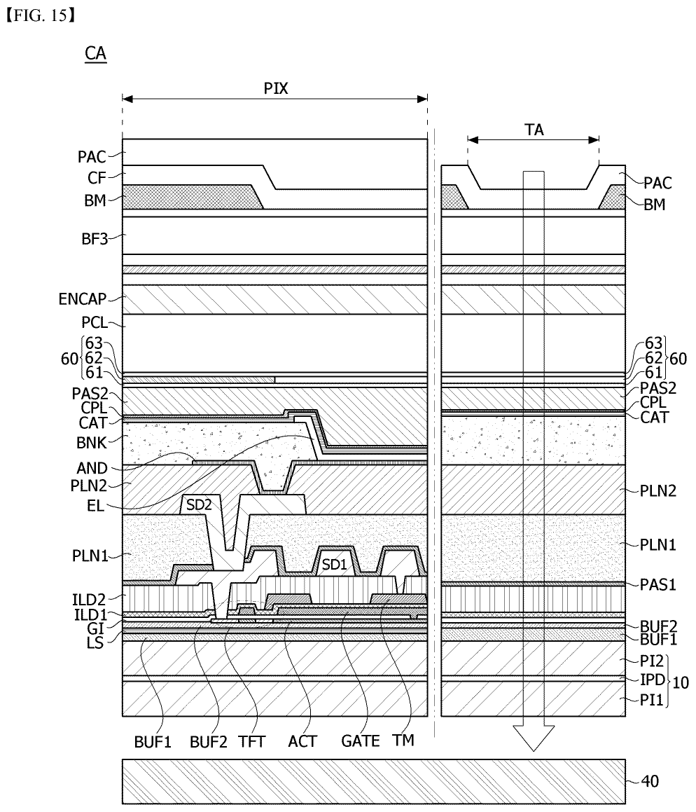

Referring to FIG. 15, a circuit layer, the light-emitting element layer, and the like may be stacked on the substrate 10 in the pixel region PIX. The substrate 10 may include a first PI substrate PI1 and a second PI substrate PI2. An inorganic film IPD may be formed between the first PI substrate PI1 and the second PI substrate PI2. The inorganic film IPD may block the penetration of moisture.

A first buffer layer BUF1 may be formed on the second PI substrate PI2. A first metal layer may be formed on the first buffer layer BUF1, and a second buffer layer BUF2 may be formed on the first metal layer.

The first metal layer may be patterned by a photolithography process. The first metal layer may include a light shield pattern LS. The light shield pattern LS may block external light so that the light does not irradiate to an active layer of a TFT, thereby preventing a photo current of the TFT formed in the pixel region from generating.

When the light shield pattern LS is formed of a metal having a low absorption coefficient of a laser wavelength used in a laser ablation process as compared to a metal layer (e.g., the cathode CAT) to be removed from the second display region CA, the light shield pattern LS may also serve to block a laser beam LB in the laser ablation process.

Each of the first and second buffer layers BUF1 and BUF2 may be made of an inorganic insulating material and may be formed of one or more insulating layers.

An active layer ACT may be made of a semiconductor material deposited on the second buffer layer BUF2 and may be patterned by a photolithography process. The active layer ACT may include an active pattern of each of TFTs of the pixel circuit and TFTs of the gate driving unit. A portion of the active layer ACT may be metallized by ion doping. The metallized portion may be used as a jumper pattern connecting the metal layers at some nodes of the pixel circuit to connect components of the pixel circuit.

A gate insulating layer GI may be formed on the second buffer layer BUF2 so as to cover the active layer ACT. The gate insulating layer GI may be made of an inorganic insulating material.

A second metal layer may be formed on the gate insulating layer GI. The second metal layer may be patterned by a photolithography process. The second metal layer may include a gate line, a gate electrode pattern GATE, a lower electrode of a storage capacitor Cst1, a jumper pattern connecting patterns of the first metal layer and a third metal layer, and the like.

A first interlayer insulating layer ILD1 may be formed on the gate insulating layer GI so as to cover the second metal layer. The third metal layer may be formed on the first interlayer insulating layer ILD1, and a second interlayer insulating layer ILD2 may cover the third metal layer. The third metal layer may be patterned by a photolithography process. The third metal layer may include metal patterns TM, such as an upper electrode of the storage capacitor Cst1. The first and second interlayer insulating layers ILD1 and ILD2 may each include an inorganic insulating material.

A fourth metal layer may be formed on the second interlayer insulating layer ILD2, and an inorganic insulating layer PAS1 and a first planarization layer PLN1 may be stacked on the fourth metal layer. A fifth metal layer may be formed on the first planarization layer PLN1.

Some patterns of the fourth metal layer may be connected to the third metal layer through a contact hole passing through the first planarization layer PLN1 and the inorganic insulating layer PAS1. The first planarization layer PLN1 and a second planarization layers PLN2 may each be made of an organic insulating material enabling surfaces thereof to be flat.

The fourth metal layer may include first and second electrodes of a TFT connected to an active pattern of the TFT through a contact hole passing through the second interlayer insulating layer ILD2. A data line DL and power lines may be implemented using a pattern SD1 of the fourth metal layer or a pattern SD2 of the fifth metal layer.

The anode AND, which is a first electrode layer of the light-emitting element OLED, may be formed on the second planarization layer PLN2. The anode AND may be connected to an electrode of a TFT used as a switch element or a driving element through a contact hole passing through the second planarization layer PLN2. The anode AND may be made of a transparent or semitransparent electrode material.

A pixel-defining film BNK may cover the anode AND of the light-emitting element OLED. The pixel-defining film BNK may be formed in a pattern that defines an emission region (or an opening region) through which light passes to the outside from each of the pixels.

An organic compound EL may be formed in the emission region of each of the pixels, which is defined by the pixel-defining film BNK. The cathode CAT, which is a second electrode layer of the light-emitting element OLED, may be formed on the entire surface of the display panel 100 so as to cover the pixel-defining film BNK and the organic compound EL. The cathode CAT may be connected to a VSS line PL3 formed of any one of the metal layers therebelow. A capping layer CPL may cover the cathode CAT. The capping layer CPL may be made of an inorganic insulating material to block the penetration of air and out-gassing of the organic insulating material, which is applied on the capping layer CPL, to protect the cathode CAT. An inorganic insulating layer PAS2 may cover the capping layer CPL, and a planarization layer PCL may be formed on the inorganic insulating layer PAS2. The planarization layer PCL may include an organic insulating material. An inorganic insulating layer ENCAP of the encapsulation layer may be formed on the planarization layer PCL.

The opening/closing module 60 may be disposed on the cathode CAT of the pixel region PIX and the light-transmitting region TA. As described above, the opening/closing module 60 may control light to be introduced into the camera 40 by switching the first light-blocking portion at the time of camera operation.

The polarizing plate 18 may be disposed on the inorganic insulating layer ENCAP to improve outdoor visibility of the display device. The polarizing plate 18 may reduce the reflection of light from a surface of the display panel 100 and block the light reflected from metal of the circuit layer 12, thereby improving the brightness of the pixels. In order to increase light transmittance, the polarizing plate 18 and the cathode CAT disposed on the light-transmitting region may be removed.

A third buffer layer BF3, a black matrix BM, the color filter CF, and a planarization layer PAC may be additionally disposed on the polarizing plate 18. According to the example, the second light-blocking portion 62b and the black matrix BM doubly prevent light from being mixed, thereby improving the contrast ratio.

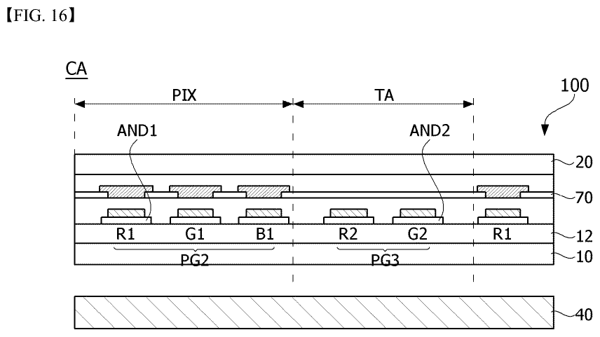

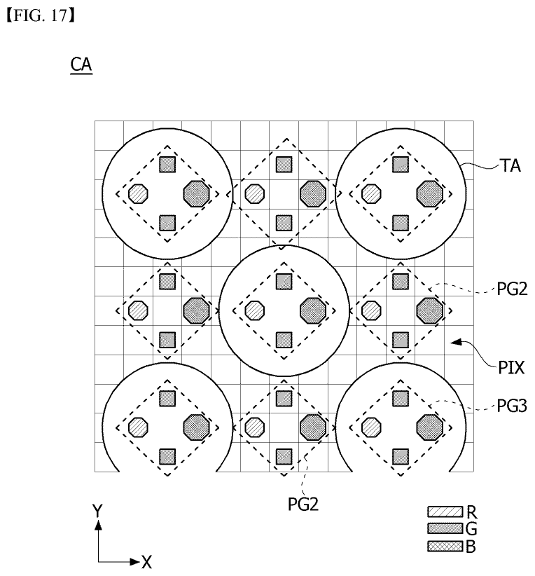

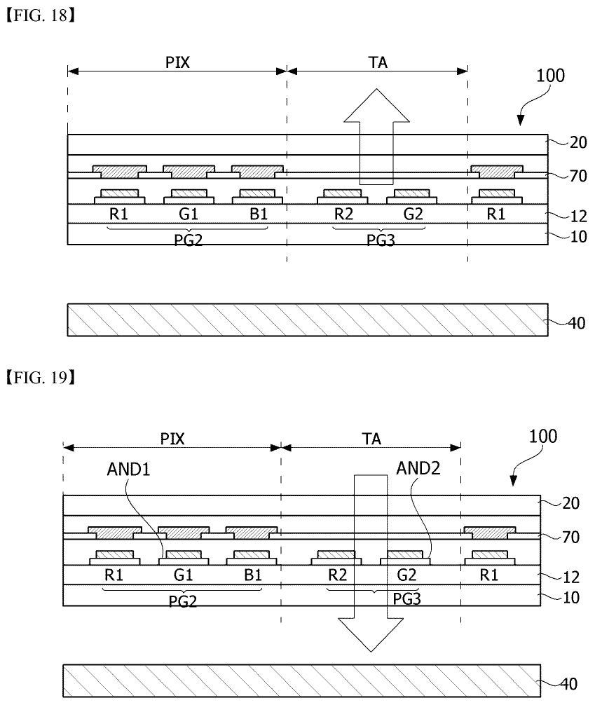

FIG. 16 is a view schematically illustrating a display device according to a second example of the present disclosure. FIG. 17 is a view illustrating a state in which a third pixel is disposed in a light-transmitting region. FIG. 18 is a view illustrating a state in which an image is output from the third pixel disposed in the light-transmitting region. FIG. 19 is a view illustrating a state in which light is incident on a camera.

Referring to FIGS. 16 and 17, pixels disposed in a second display region CA may include second pixels PG2 disposed in a plurality of pixel regions PIX and third pixels PG3 disposed in a plurality of light-transmitting regions TA. According to the example, the pixels may also be disposed in the light-transmitting regions TA. Thus, the total light-transmitting area of each light-transmitting region TA may be slightly reduced by the presence of the third pixels P3.

According to the example, since pixels are disposed in the light-transmitting regions TA, the number of pixels per unit area (PPI) of the second display region CA may be the same as that of a first display region DA. In this case, the pixels may be formed at one time using one fine metal mask (FMM) in the first display region DA and the second display region CA, thereby reducing manufacturing costs and shortening manufacturing time.

The second pixel PG2 and the third pixel PG3 may be independently driven. Accordingly, the third pixel PG3 may include a plurality of light-emitting elements as well as a driving circuit configured to drive each of the light-emitting elements. According to the example, the driving circuit which drives the third pixel PG3 may be disposed in the pixel region PIX in order to increase the area of the light-transmitting region TA.

Referring to FIG. 18, when an image is output from a display panel 100, the image may also be output from the third pixel PG3 through the light-transmitting region TA. The second pixel PG2 and the third pixel PG3 may simultaneously output an image, or only one of the second pixel PG2 and the third pixel PG3 may output the image. The first display region DA and the second display region CA may output images with the same resolution.

Referring to FIG. 19, when a camera 40 is in operation, the third pixel PG3 may not output an image. Thus, light may be incident on the camera 40 through the light-transmitting region TA. However, the present disclosure is not necessarily limited thereto, and at least one of sub-pixels R2 and G2 of the third pixel PG3 may output light even when the camera 40 is in operation.

In order to increase the area of the light-transmitting region TA, the driving circuit of the third pixel PG3 may be formed of a transparent electrode. As an example, a second anode AND2 of the third pixel PG3 may be made transparent. As an example, a first anode AND1 of the second pixel PG2 may be manufactured as a reflective electrode such as silver (Ag), and the second anode AND2 of the third pixel PG3 may be manufactured as a transparent electrode such as ITO. A first anode AND1 of the second pixel PG2 and the second anode AND2 of the third pixel PG3 may be formed of a transparent electrode. Although only the anode AND is illustrated in the present example, a circuit wiring disposed in the light-transmitting region TA of the driving circuit may be manufactured of a transparent electrode.

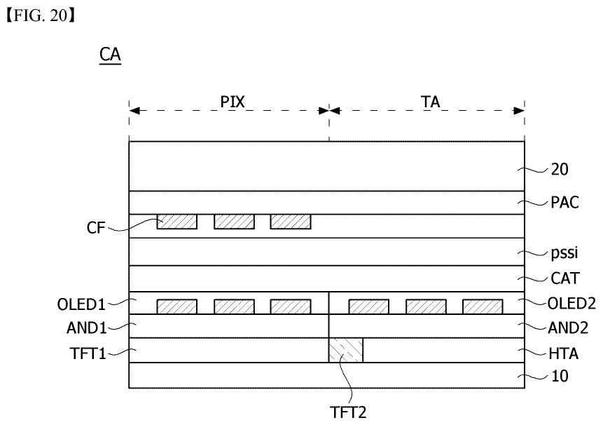

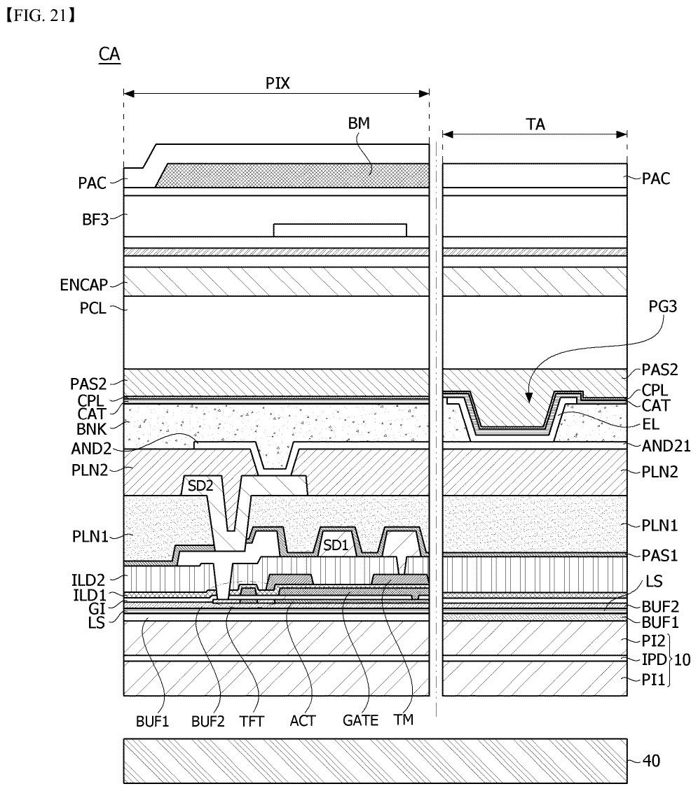

FIG. 20 is an exemplary view illustrating a schematic cross-sectional structure of the second display region according to the second example. FIG. 21 is an exemplary view illustrating a detailed cross-sectional structure of the second display region according to the second example.

Referring to FIGS. 20 and 21, the second display region CA may be divided into the light-transmitting region TA and the pixel region PIX. In the pixel region PIX and the light-transmitting region TA, the anodes AND1 and AND2 and light-emitting element layers OLED1 and OLED2 may be disposed on driving circuits TFT1 and TFT2, respectively.

The driving circuit TFT2 of the light-transmitting region TA may be disposed in the pixel region PIX in order to widen the light-transmitting region TA as much as possible.

The second anode AND2 of the driving circuit TFT2 of the third pixel PG3 may extend to the light-transmitting region TA. As described above, the second anode AND2 may be formed as a transparent electrode to transmit most of light. Accordingly, sufficient light may be injected into the camera 40 while implementing an image in the light-transmitting region TA.

A cathode CAT, a color filter CF, a planarization film PAC, and a cover glass 20 may be disposed in the pixel region PIX and the light-transmitting region TA. The color filter CF may not be formed on the light-transmission region TA.

Referring to FIG. 21, the driving circuit such as an active layer ACT, a gate electrode GATE, a drain electrode, and a source electrode may be disposed mostly outside the light-transmitting region to increase an area of the light-transmitting region. In addition, the anode AND2 may include an extension portion AND21 extending to the light-transmitting region TA, and an organic emission layer EL may be formed on the extension portion AND21. Thus, most of light can be transmitted.

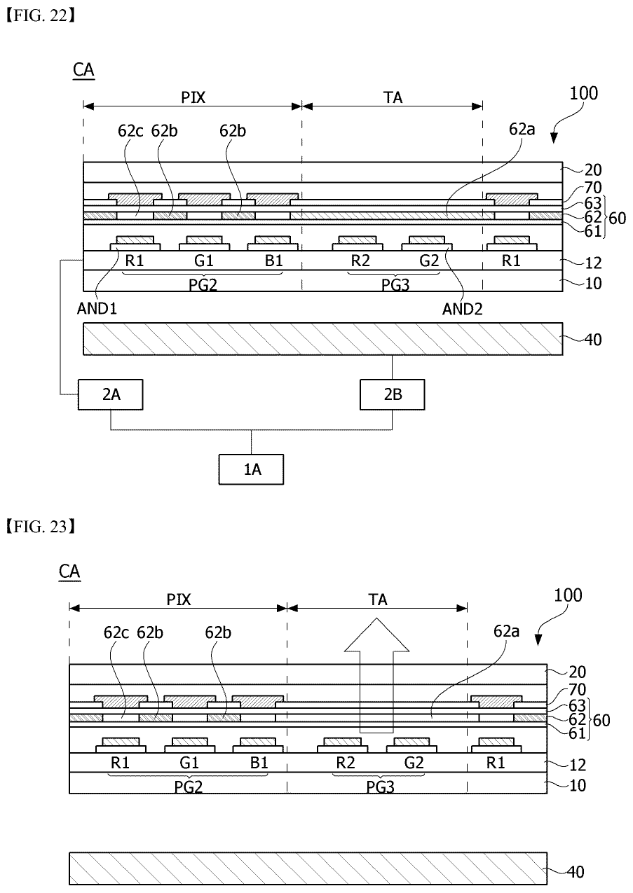

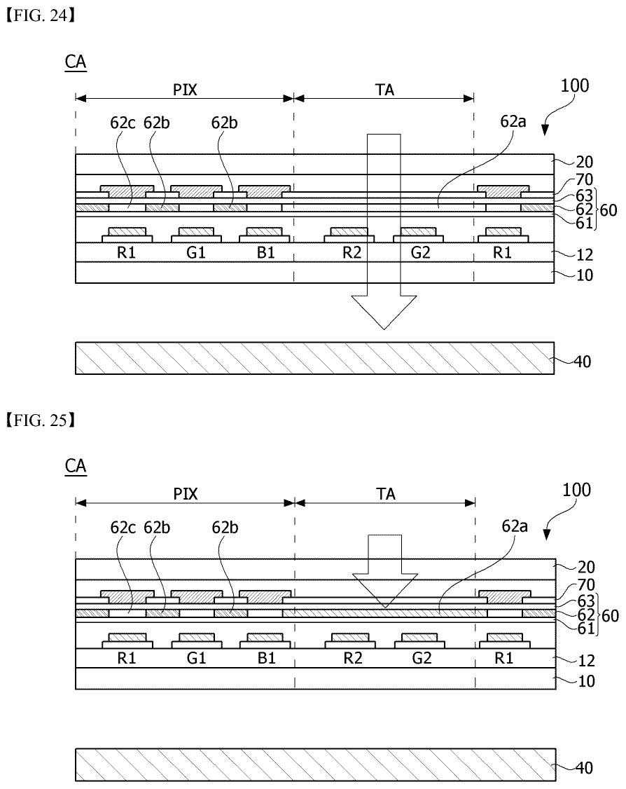

FIG. 22 is a view schematically illustrating a display device according to a third example of the present disclosure. FIG. 23 is a view illustrating a state in which a light-blocking portion is open and an image is output from a third pixel disposed in a light-transmitting region. FIG. 24 is a view illustrating a state in which the light-blocking portion is open and light is incident on a camera. FIG. 25 is a view illustrating a state in which the light-blocking portion blocks light.

Referring to FIG. 22, the display device may have a structure in which the first example and the second example are combined. That is, an opening/closing module 60 may be disposed in a display panel 100, and a third pixel PG3 may be disposed in a light-transmitting region TA.

The opening/closing module 60 may include a first light-blocking portion 62a disposed in the light-transmitting region TA and a second light-blocking portion 62b disposed in a pixel region PIX. The first light-blocking portion 62a is disposed above the third pixel PG3 to block light that is incident on the light-transmitting region TA when a camera 40 and the third pixel PG3 are not driven.

A display panel control unit 2A may receive an open timing signal of the opening/closing module 60 which is synchronized with an output timing of the third pixel PG3 and a driving timing of the camera 40.

Referring to FIG. 23, when sub-pixels R2 and G2 of the third pixel PG3 output images, power is applied to a first transparent electrode 61 and a second transparent electrode 63 so that the first light-blocking portion 62a may be switched to a light transmitting mode. Thus, the third pixel PG3 together with the second pixel PG2 may implement an image. In this case, the second light-blocking portion 62b is disposed between sub-pixels R1, G1, and B1 of the second pixel PG2 to prevent colors from being mixed in the color filter 70.

Referring to FIG. 24, when the camera 40 is in operation, the first light-blocking portion 62a of the opening/closing module 60 may be switched to a light-transmitting mode to allow light to pass therethrough. Accordingly, sufficient light can be incident on the camera 40.

The second light-blocking portion 62b disposed between the pixels may continue to block light. However, the present disclosure is not necessarily limited thereto, and when the first light-blocking portion 62a operates in the light transmitting mode for transmitting light, the second light-blocking portion 62b may also be switched to transmit the light. This configuration may further improve the performance of the camera 40 by increasing the overall amount of light transmitted to a second display region CA.

Accordingly, when the second pixel PG2 and the third pixel PG3 are driven, the second light-blocking portion 62b may block light to perform a black matrix function, but when the camera 40 is driven, the second light-blocking portion 62b may be switched to the light transmitting mode to increase the amount of light. Accordingly, the second light-blocking portion 62b may be controlled independently from the first light-blocking portion 62a.

Referring to FIG. 25, when pixel data is not written to the third pixel PG3 and the camera 40 does not operate, the first light-blocking portion 62a and the second light-blocking portion 62b may block light incident on the light-transmitting region TA. Accordingly, it is possible to prevent the camera 40 from being visible from the outside.

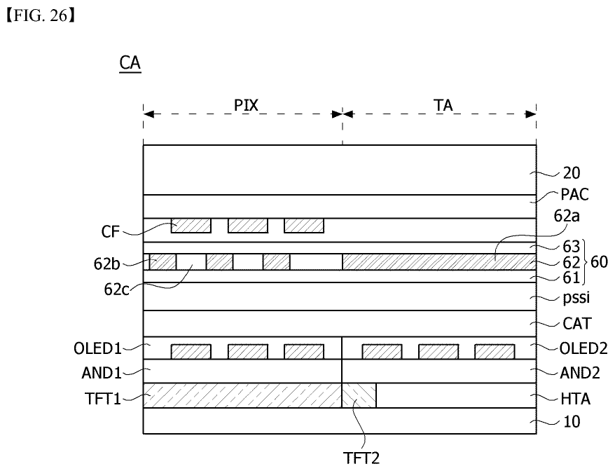

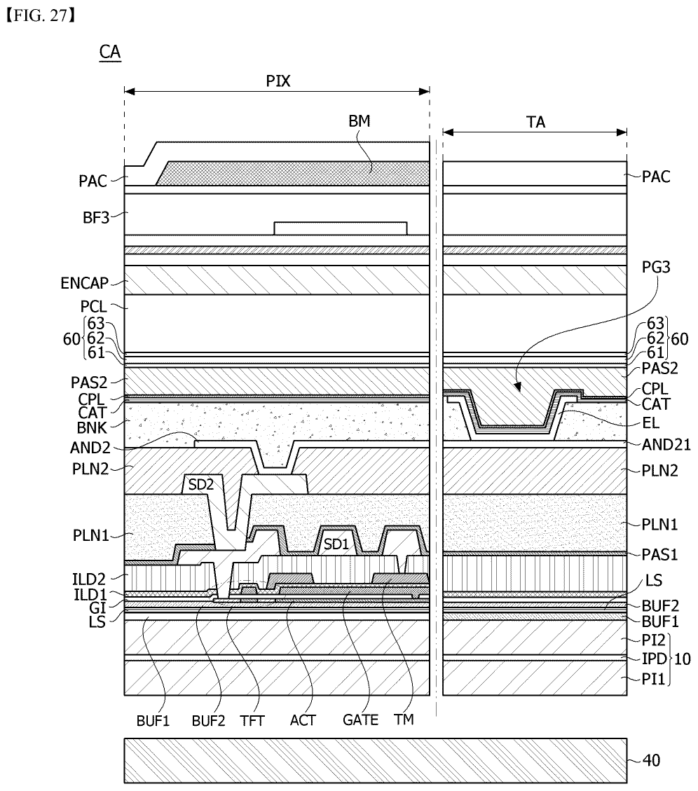

FIG. 26 is an exemplary view illustrating a schematic cross-sectional structure of the second display region according to the third example. FIG. 27 is an exemplary view illustrating a detailed cross-sectional structure of the second display region according to the third example.

Referring to FIGS. 26 and 27, the second display region CA may be divided into the light-transmitting region TA and the pixel region PIX on a substrate 10. In the pixel region PIX and the light-transmitting region TA, anodes AND1 and AND2 and light-emitting element layers OLED1 and OLED2 may be disposed on driving circuits TFT1 and TFT2, respectively.

The driving circuit TFT2 of the light-transmitting region TA may be disposed in the pixel region PIX in order to widen the light-transmitting region TA as much as possible. The second anode AND2 may extend to the light-transmitting region TA. As described above, the second anode AND2 is formed as a transparent electrode to transmit most of light. Accordingly, sufficient amount of light may be injected into the camera 40 while implementing an image in the light-transmitting region TA.

A cathode CAT and the opening/closing module 60 may be disposed in the pixel region PIX and the light-transmitting region TA. The first light-blocking portion 62a of the opening/closing module 60 may be disposed in the light-transmitting region TA, and the second light-blocking portion 62b may be disposed in the pixel region PIX. A color filter CF, a planarization film PAC, and a cover glass 20 may be disposed on the opening/closing module 60.

Referring to FIG. 27, the driving circuit such as an active layer ACT, a gate electrode GATE, a drain electrode, and a source electrode may be disposed mostly outside the light-transmitting region to increase an area of the light-transmitting region. In addition, the second anode AND2 may include an extension portion AND21 extending to the light-transmitting region TA, and an organic emission layer EL may be formed on the extension portion AND21. Thus, most of light can be transmitted.

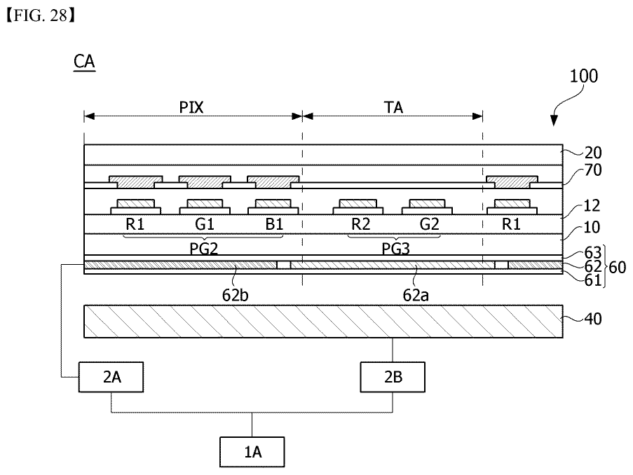

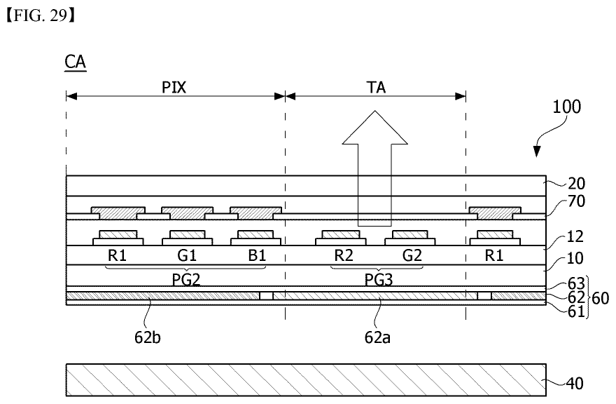

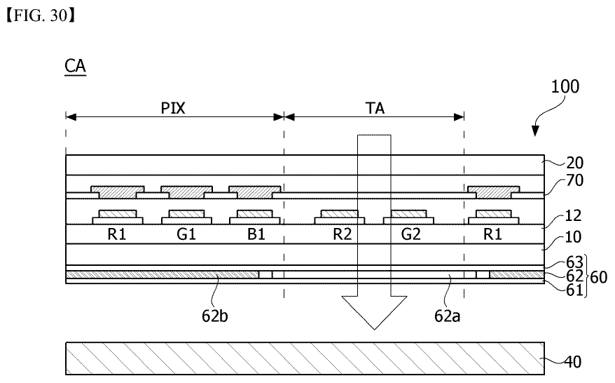

FIG. 28 is a view schematically illustrating a display device according to a fourth example of the present disclosure. FIG. 29 is a view illustrating a state in which an image is output from a third pixel disposed in a light-transmitting region. FIG. 30 is a view illustrating a state in which light is incident on a camera.

Referring to FIG. 28, the display device according to the example may include an opening/closing module 60 disposed in a lower portion of a display panel 100. The opening/closing module 60 may be integrally manufactured with the lower portion of the display device and may also be manufactured separately from the display panel 100.

The opening/closing module 60 may be disposed below the substrate 10. The opening/closing module 60 may include a first light-blocking portion 62a disposed in a light-transmitting region TA and a second light-blocking portion 62b disposed in a pixel region PIX. The second light-blocking portion 62b may be disposed on the entire lower portion of the pixel region PIX and serve as a black matrix. Accordingly, the second light-blocking portion 62b may also be disposed below a second pixel PG2.

Referring to FIG. 29, when an image is output from a third pixel PG3, the first light-blocking portion 62a of the opening/closing module 60 may be open to allow light to pass therethrough. At this time, the second light-blocking portion 62b may block incident light.

Referring to FIG. 30, when a camera 40 is in operation, the first light-blocking portion 62a of the opening/closing module 60 may be open to allow light to pass therethrough. In this case, the second light-blocking portion 62b may block incident light, but is not necessarily limited thereto, and may increase the amount of light incident on the camera 40.

When pixel data is not written to the third pixel PG3 and the camera 40 does not operate, the first light-blocking portion 62a may block light incident on the light-transmitting region TA.

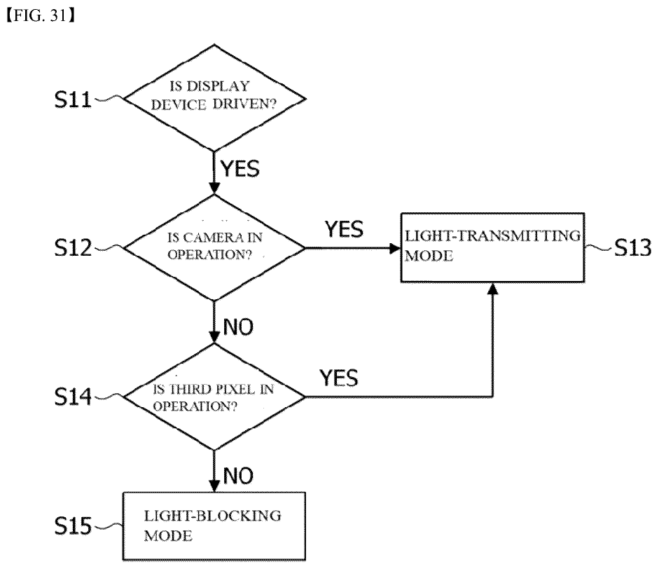

FIG. 31 is a flowchart illustrating a method of driving a display device according to one example of the present disclosure.

Referring to FIG. 31, the method of driving a display device according to the example includes determining whether the display device is driven (S11), determining whether a camera 40 is in operation (S12), determining whether a third pixel PG3 is in operation (S14), and selecting a light-transmitting mode or a light-blocking mode depending on whether the camera 40 and the third pixel PG3 are in operation (S13 and S15).

In the determining of whether the display device is driven (S11), whether the display device is in a turned-on state or a turned-off state may be determined. As an example, when a power signal is applied to the display device, driving the display device according to the example may be started.

In the determining of whether the camera 40 is in operation (S12), a camera driving signal may be transmitted to a camera control unit from a main circuit. In this case, the main circuit may transmit an opening/closing module control signal synchronized with the camera driving signal to the display panel control unit. Accordingly, the display panel control unit may determine that the camera is in operation at a time point determined from timing data.

In the determining of whether the third pixel is in operation (S14), control data received from the display panel control unit may be analyzed to determine whether the third pixel is in operation.

In the selecting of the mode (S13 or S15), when it is determined that the camera or the third pixel is in operation, the display panel control unit may apply power to the opening/closing module to pass light therethrough at a corresponding time point (light-transmitting mode, S13). However, when it is determined that the camera does not operate and the third pixel does not operate, a light-blocking mode may be maintained as it is (S14).

According to an example, there is an advantage in that an imaging region is not visible from the outside while maintaining modulation transfer function (MTF) performance of a camera.

In addition, a contrast ratio of output light can be improved by a light-blocking layer. Accordingly, low-power driving can be enabled.

Effects of the present disclosure will not be limited to the above-mentioned effects and other unmentioned effects will be clearly understood by those skilled in the art from the following claims.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

Also disclosed herein are a number of examples according to the following numbered clauses.

Clause 1. A display device comprising:
a display panel including a first display region in which a plurality of first pixels are disposed, a second display region including pixel regions in which a plurality of second pixels are disposed and a plurality of light-transmitting regions, and an opening/closing module configured to control light passing through the plurality of light-transmitting regions; and
an optical sensor disposed below the display panel,
wherein the opening/closing module opens the light-transmitting region when the optical sensor is driven, and blocks the light-transmitting region when the optical sensor is not driven.

Clause 2. The display device of clause 1, wherein a pixel density of the second display region is lower than a pixel density of the first display region.

Clause 3. The display device of any preceding clause, wherein the display panel includes a plurality of third pixels disposed in the plurality of light-transmitting regions.

Clause 4. The display device of clause 3, wherein a pixel density of the second display region is equal to a pixel density of the first display region.

Clause 5. The display device of clause 3 or clause 4, wherein the opening/closing module opens the light-transmitting region when an image is output from the third pixel.

Clause 6. The display device of clause 5, wherein the opening/closing module blocks the light-transmitting region when the optical sensor and the third pixel are not driven.

Clause 7. The display device according to any of clauses 3 to 7, wherein a first anode driving the second pixel is a reflective electrode, and a second anode driving the third pixel is a transparent electrode.

Clause 8. The display device of any preceding clause, wherein the light-transmitting region includes:
a buffer layer disposed on a substrate;
a gate insulating film disposed on the buffer layer; and
a cathode disposed on the gate insulating film, and
the opening/closing module is disposed on the cathode.

Clause 9. The display device of clause 3, wherein the light-transmitting region includes:
a buffer layer disposed on a substrate;
a driving transistor disposed on the buffer layer;
an anode disposed on the driving transistor;
an organic emission layer disposed on the anode; and
a cathode disposed on the organic emission layer, and
the opening/closing module is disposed on the cathode.

Clause 10. The display device according to any of clauses 1 to 8, wherein the light-transmitting region includes:
a buffer layer disposed on a substrate;
a gate insulating film disposed on the buffer layer; and a cathode disposed on the gate insulating film, and
the opening/closing module is disposed below the substrate.

Clause 11. The display device of clause 9, wherein the driving transistor includes an active layer, a gate electrode disposed on the active layer, and a drain electrode and a source electrode electrically connected to the active layer,
wherein the active layer, the gate electrode, the drain electrode, and the source electrode are disposed outside the light-transmitting region.

Clause 12. The display device of clause 9 or clause 11, wherein the anode includes an extension portion extending to the light-transmitting region,
wherein the extension portion is a transparent electrode.

Clause 13. The display device of clause 3, wherein the opening/closing module includes:
a first transparent electrode;
a light-blocking layer disposed on the first transparent electrode; and
a second transparent electrode disposed on the light-blocking layer,
wherein the light-blocking layer includes a first light-blocking portion disposed at a position corresponding to each of the plurality of light-transmitting regions.

Clause 14. The display device of clause 13, wherein the light-blocking layer includes a second light-blocking portion disposed outside the light-transmitting region, wherein the second light-blocking portion includes openings disposed on the plurality of second pixels.

Clause 15. The display device of clause 13 or clause 14, wherein the plurality of light-blocking portions include a photochromic material that allows light to pass therethrough when power is applied thereto.

Clause 16. The display device of claim 15, wherein the opening/closing is configured to apply power to the photochromic material when the optical sensor is driven.

Clause 17. The display device of claim 14, wherein the second light-blocking portion blocks light when the second pixel and the third pixel output light, and transmits light when the optical sensor is driven.

Clause 18. The display device according to any preceding claim, wherein the optical sensor is located under the second display region.

Clause 19. The display device according to any preceding claim, further comprising a high light-transmitting region located under the plurality of light-transmitting regions.

Clause 20. The display device according to claim 19, wherein the high light-transmitting region has a higher light-transmittance than a region located under the plurality of second pixels.

Clause 21. The display device according to any preceding claim, wherein the first display area surrounds the second display area.

Clause 22. A method of driving a display device according to any preceding claim, the method comprising:
determining whether the optical sensor is in operation; and
causing the opening/closing module to open the light-transmitting region when it is determined that the optical sensor is in operation.

Clause 23. The method of claim 22, further comprising:
causing the opening/closing module to close the light-transmitting region when it is determined that the optical sensor is not in operation.

Clause 24. A method of driving a display device according to claim 3, the method comprising:
determining whether the optical sensor is in operation;
determining whether the plurality of third pixels are in operation; and
causing the opening/closing module to open the light-transmitting region when it is determined that at least one of the optical sensor and the plurality of third pixels are in operation.

Clause 25. The method of 24, further comprising:
causing the opening/closing module to close the light-transmitting region when it is determined that neither the optical sensor nor the plurality of third pixels are in operation.

What is claimed is:

1. A display device, comprising:
a display panel including:
a first display region in which a plurality of first pixels are disposed,
a second display region including pixel regions and a plurality of light-transmitting regions, wherein a plurality of second pixels are disposed in the pixel regions, and an opening/closing module configured to control light passing through the plurality of light-transmitting regions; and
an optical sensor disposed below the display panel,
wherein the opening/closing module is configured to open the light-transmitting region when the optical sensor is driven, and block the light-transmitting region when the optical sensor is not driven.

2. The display device of claim 1, wherein a pixel density of the second display region is lower than a pixel density of the first display region.

3. The display device of claim 1, wherein the display panel includes a plurality of third pixels disposed in the plurality of light-transmitting regions.

4. The display device of claim 3, wherein a pixel density of the second display region is equal to a pixel density of the first display region.

5. The display device of claim 3, wherein the opening/closing module is configured to open the light-transmitting regions when an image is output from the third pixels.

6. The display device of claim 5, wherein the opening/closing module is configured to block the light-transmitting regions when the optical sensor and the third pixels are not driven.

7. The display device of claim 3, wherein a first anode driving the second pixels is a reflective electrode, and
a second anode driving the third pixels is a transparent electrode.

8. The display device of claim 1, wherein the light-transmitting region includes:
a buffer layer disposed on a substrate;
a gate insulating film disposed on the buffer layer; and
a cathode disposed on the gate insulating film,
wherein the opening/closing module is disposed on the cathode.

9. The display device of claim 3, wherein the light-transmitting region includes:
a buffer layer disposed on a substrate;
a driving transistor disposed on the buffer layer;
an anode disposed on the driving transistor;
an organic emission layer disposed on the anode; and
a cathode disposed on the organic emission layer,
wherein the opening/closing module is disposed on the cathode.

10. The display device of claim 1, wherein the light-transmitting region includes:
a buffer layer disposed on a substrate;
a gate insulating film disposed on the buffer layer; and
a cathode disposed on the gate insulating film,
wherein the opening/closing module is disposed below the substrate.

11. The display device of claim 9, wherein the driving transistor includes an active layer, a gate electrode disposed on the active layer, and a drain electrode and a source electrode electrically connected to the active layer,
wherein the active layer, the gate electrode, the drain electrode, and the source electrode are disposed outside the light-transmitting region.

12. The display device of claim 9, wherein the anode includes an extension portion extending to the light-transmitting region,
wherein the extension portion is a transparent electrode.

13. The display device of claim 3, wherein the opening/closing module includes:
a first transparent electrode;
a light-blocking layer disposed on the first transparent electrode; and
a second transparent electrode disposed on the light-blocking layer,
wherein the light-blocking layer includes a first light-blocking portion disposed at a position corresponding to each of the plurality of light-transmitting regions.

14. The display device of claim 13, wherein the light-blocking layer includes a second light-blocking portion disposed outside the light-transmitting region, wherein the second light-blocking portion includes openings disposed on the plurality of second pixels.

15. The display device of claim 14, wherein the plurality of light-blocking portions include a photochromic material that allows light to pass therethrough when power is applied thereto.

16. The display device of claim 15, wherein the opening/closing module is configured to apply power to the photochromic material when the optical sensor is driven.

17. The display device of claim 14, wherein the second light-blocking portion blocks light when the second pixel and the third pixel output light, and transmits light when the optical sensor is driven.

18. The display device of claim 1, wherein the optical sensor is located under the second display region.

19. The display device of claim 1, further comprising a high light-transmitting region located under the plurality of light-transmitting regions, and
wherein the high light-transmitting region has a higher light-transmittance than a region located under the plurality of second pixels.

20. The display device of claim 1, wherein the first display area surrounds the second display area.
